(19) United States
(12) Patent Application Publication
(10) Pub. No.: US 2006/0226489 A1
(43) Pub. Date: Oct. 12, 2006

(54) System and methods for retention-enhanced programmable shared gate logic circuit

(75) Inventors: Bin Wang, Seattle, WA (US); Todd E. Humes, Shoreline, WA (US)

Correspondence Address: MERCHANT & GOULD PC, P.O. BOX 2903, MINNEAPOLIS, MN, 55402-0903, US

(73) Assignee: IMPINJ, INC., Seattle, WA (US)

(21) Appl. No.: 11/095,938

(22) Filed: Mar. 30, 2005

(51) Int. Cl. H01L 29/76

(52) U.S. Cl. 257/365

(57) ABSTRACT

Retention-enhanced, programmable, shared floating gate logic circuits are employed as NVM cells. In one embodiment, the NVM cell is formed by a dual transistor logic gate circuit with a shared floating gate. The logic circuit is an inverter. The shared floating gate is doped partially or completely with p-type impurities to enhance retention. A charge adjustment circuit is arranged to inject and remove electrons to and from the shared floating gate determining the output of the logic gate circuit when supply voltage is applied to the logic gate circuit. In another embodiment, four transistors are employed to form another logic circuit such as a NOR gate or a NAND gate.

### RELATED APPLICATIONS

This application is related to U.S. Utility application Ser. No. 10/813,907 (IMPJ-0027A) filed on Mar. 30, 2004, Ser. No. 10/814,866 (IMPJ-0027B) filed on Mar. 30, 2004, and Ser. No. 10/814,868 (IMPJ-0027C) filed on Mar. 30, 2004. All three Applications are incorporated herein by reference.

### FIELD OF THE INVENTION

The present invention relates to non-volatile memory cell and structure, and more particularly, to methods and apparatus for programming, reading, erasing, and forming such structures.

### BACKGROUND OF THE INVENTION

Memory devices are electronic devices arranged to store electrical signals. For example, a basic memory element may be a fuse that can either be open or be closed. Open and closed states of the fuse may be used to designate one bit of information corresponding to a value of 1 or 0. A plurality of memory elements can be combined in various arrangements in order to store multiple bits arranged in words or other combinations. Various electronic circuits including semiconductor devices such as transistors are used as memory elements.

Memory elements may be classified in two main categories: volatile and nonvolatile. Volatile memory loses any data as soon as the system is turned off. Thus, it requires constant power to remain viable. Most types of random access memory (RAM) fall into this category. Non-volatile memory does not lose its data when the system or device is turned off. A non-volatile memory (NVM) device may be implemented as a MOS transistor that has a source, a drain, an access or a control gate, and a floating gate. It is structurally different from a standard MOSFET in its floating gate, which is electrically isolated, or “floating”. Non-volatile memories may be subdivided into two main classes: floating gate and charge-trapping.

In floating gate memory circuits, electrons are typically transferred from the floating gate to the substrate or from the substrate to the floating gate by bi-directional tunneling through a thin silicon dioxide (SiO₂) layer. Tunneling is the process by which an NVM can be either erased or programmed and is usually dominant in thin oxides of thicknesses less than 12 nm. Storage of the charge on the floating gate allows the threshold voltage to be electrically altered between a low and a high value to represent logic 0 and 1, respectively. Other types of electron injection methods such as hot electron injection may also be employed in floating gate devices. In floating gate memory devices, charge or data is stored in the floating gate and is retained when the power is removed.

In charge-trapping memory devices, charge or data is stored in the discrete nitride traps and is also retained when the power is removed. Charge-trapping devices are typically used in MNOS (Metal Nitride Oxide Silicon), SNOS (Silicon Nitride Oxide Semiconductor), and SONOS (Silicon Oxide Nitride Oxide Semiconductor) technologies. The charges in MNOS memories may be injected from the channel region into the nitride by quantum mechanical tunneling through an ultra-thin oxide (UTO).

Non-volatile memory arrays include a plurality of NVM cells arranged in rows and columns. In general, single-transistor n-channel NVM cells operate as follows. During an erase operation, electrons are removed from a floating gate of the NVM cell, thereby lowering the threshold voltage of the NVM cell. During a program operation, electrons are inserted into the floating gate of the NVM cell, thereby raising the threshold voltage of the NVM cell. Thus, during program and erase operations, the threshold voltages of selected NVM cells are changed. During a read operation, read voltages are applied to selected NVM cells. In response, read currents flow through these selected NVM cells. The magnitudes of the read currents are dependent upon the threshold voltages of the selected NVM cells.

### SUMMARY

The disclosure facilitates storage of digital information in a non-volatile memory circuit. Accordingly, the disclosure provides programming, erasing, and reading of non-volatile memory arrays.

In some embodiments, NVM cells are formed by a dual transistor logic gate circuit with a shared floating gate. The shared floating gate is doped partially or completely with p-type impurities to enhance retention. A charge adjustment circuit is arranged to inject and remove electrons to and from the shared floating gate determining the output of the logic gate circuit when supply voltage is applied to the logic gate circuit.

In the dual transistor embodiment, the logic gate circuit may be an inverter. In other embodiments, the NVM cell may comprise four transistors and include other logic circuits such as NOR and NAND.

While example embodiments are shown using a floating gate, dual transistor storage element, the principles disclosed herein may be implemented in other types of NVM cells. Thus, the invention is not limited to the illustrated examples.

### BRIEF DESCRIPTION OF THE DRAWINGS

Non-limiting and non-exhaustive embodiments are described with reference to the following drawings.

FIG. 1 is a block diagram of a dual transistor, retention-enhanced, shared gate logic circuit;

FIG. 2 is a block diagram of the logic circuit of FIG. 1 with a charge adjustment circuit that is arranged to adjust a charge storage level of the shared floating gate of the logic circuit as a non-volatile memory (NVM) cell;

FIG. 3 is a block diagram of the logic circuit of FIG. 1 with a charge adjustment circuit and a programming circuit that is arranged to control and provide a high voltage supply to the charge adjustment circuit;

FIG. 4 is a block diagram of a four transistor, retention-enhanced, dual shared gate logic circuit;

FIG. 5 schematically illustrates the dual transistor, retention-enhanced, shared gate logic circuit of FIG. 1;

FIG. 6A is a conceptual top view of a dual transistor logic circuit comprising metal oxide semiconductor field effect transistors with a shared gate entirely doped with p+ implants according to one embodiment;

FIG. 6B is a conceptual top view of a dual transistor logic circuit comprising metal oxide semiconductor field effect transistors with a shared gate partially doped with p+ and n− implants according to another embodiment;

FIG. 7A is a cross-sectional view of the dual transistor logic circuit of FIG. 6A with the shared gate entirely doped with p+ implants according to one embodiment;

FIG. 7B is a cross-sectional view of the dual transistor logic circuit of FIG. 6B with the shared gate doped with p+ and n− implants according to another embodiment;

FIG. 8 schematically illustrates the four transistor logic circuit of FIG. 4 in a NOR configuration; and

FIG. 9 schematically illustrates the four transistor logic circuit of FIG. 4 in a NAND configuration.

### DETAILED DESCRIPTION

Various embodiments of the present invention will be described in detail with reference to the drawings, where like reference numerals represent like parts and assemblies throughout the several views. Reference to various embodiments does not limit the scope of the invention, which is limited only by the scope of the claims attached hereto. Additionally, any examples set forth in this specification are not intended to be limiting and merely set forth some of the many possible embodiments for the claimed invention.

Throughout the specification and claims, the following terms take at least the meanings explicitly associated herein, unless the context clearly dictates otherwise. The meanings identified below are not intended to limit the terms, but merely provide illustrative examples for the terms. The meaning of “a,” “an,” and “the” includes plural reference, the meaning of “in” includes “in” and “on.” The term “connected” means a direct electrical connection between the items connected, without any intermediate devices. The term “coupled” means either a direct electrical connection between the items connected or an indirect connection through one or more passive or active intermediary devices. The term “circuit” means either a single component or a multiplicity of components, either active and/or passive, that are coupled together to provide a desired function. The term “signal” means at least one current, voltage, charge, temperature, data, or other measurable quantity. The term “cell” means a unit NVM circuit comprising of a programming and a storage element that are arranged to store one bit. The term “array, refers to a plurality of NVM cells arranged in columns and rows.

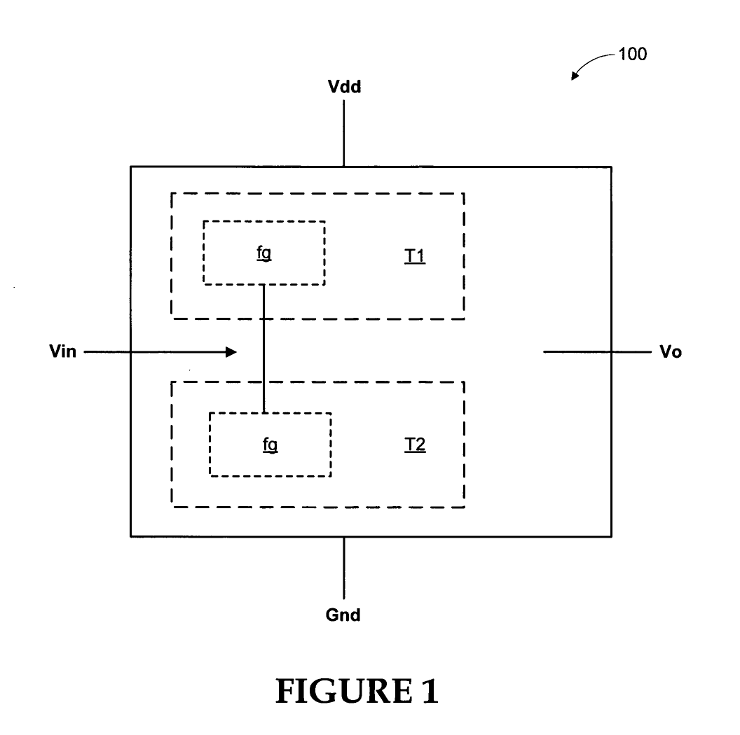

FIG. 1 is a block diagram of dual transistor, retention-enhanced, shared gate logic circuit 100.

In general, dual-transistor NVM cells operate as follows. During an erase operation, electrons are removed from a floating gate of the NVM cell, thereby adjusting and lowering the switch point voltage of the dual transistor NVM cell. During a program operation, electrons are inserted onto the floating gate of the NVM cell, thereby adjusting and raising the switch point voltage of the dual transistor NVM cell. Thus, during program and erase operations, the switch point voltages of selected NVM cells are changed. During a read operation, read voltages are applied to selected NVM cells. In response, output voltage of these selected NVM cells reflect a bit value based on the stored charges in their floating gate.

Floating gate type NVM cells may include charge adjustment circuits that are arranged to inject electrons to or remove electrons from the floating gate of the storage element employing mechanisms such as impact-ionized hot-electron injection, Fowler-Nordheim (FN) tunneling, channel hot-electron tunneling, or band-to-band tunneling induced electron injection.

Logic circuit 100 includes transistors T1 and T2. T1 and T2 share a floating gate fg. Logic circuit 100 is arranged to receive supply voltages Vdd and Gnd. Furthermore, programming, erase or read voltage Vin is coupled to shared floating gate fg. Logic circuit 100 provides output voltage Vo in response to the coupled voltages. Vo represents a bit value stored in logic circuit 100 in response to programming voltage Vin.

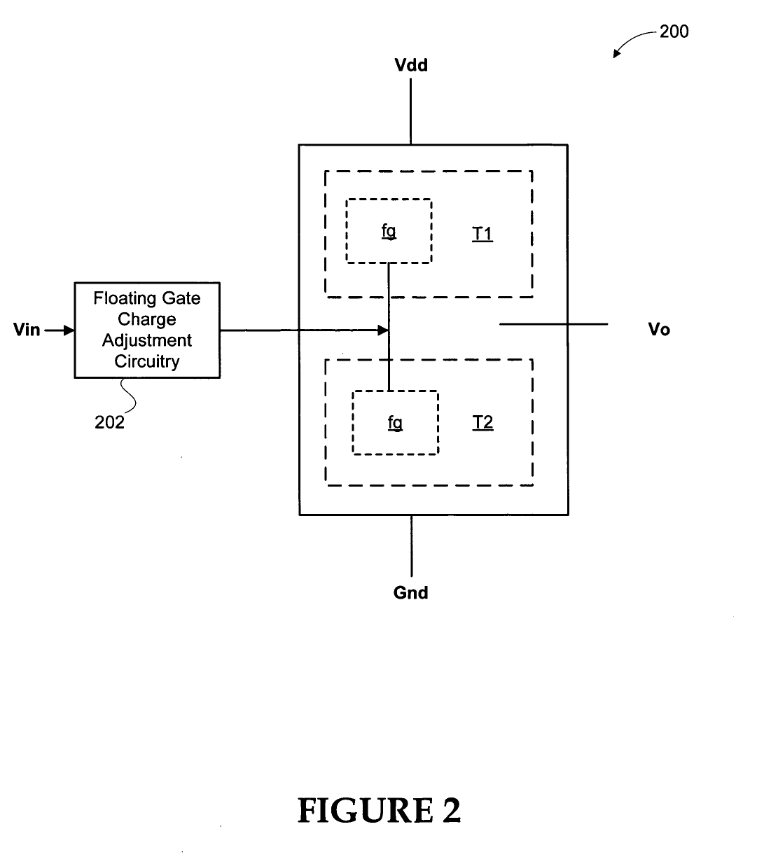

FIG. 2 is a block diagram of logic circuit 200 with a charge adjustment circuit that is arranged to adjust a charge storage level of the shared floating gate of the logic circuit as an NVM cell.

Logic circuit 200 is arranged to operate as described above for logic circuit 100. Floating gate charge adjustment circuit 202 is arranged to couple input voltage Vin on floating gate fg based on a programming signal. In one embodiment, floating gate charge adjustment circuit 202 may include a first programming transistor and a second programming transistor that are coupled together at their gate terminals. A source, a drain, and an n-well terminal of first programming transistor may be coupled together to a first programming voltage. A source, a drain, and an n-well terminal of the second programming transistor may be coupled together to a second programming voltage.

Floating gate charge adjustment circuit 202 may be arranged such that electrons are injected to shared floating gate fg when the first programming voltage has a high value and the second programming voltage has a low value. Electrons may be removed from the shared floating gate, when first programming voltage has the low value and the second programming voltage is set to the high value.

A structure and operation of a programming circuit for a shared floating gate NVM cell is discussed in detail in U.S. Patent Application No. (not yet assigned) (Atty. Docket No. 50133-12US01), filed on even date herewith, entitled “COMPACT NON-VOLATILE MEMORY CELL AND ARRAY SYSTEM.”

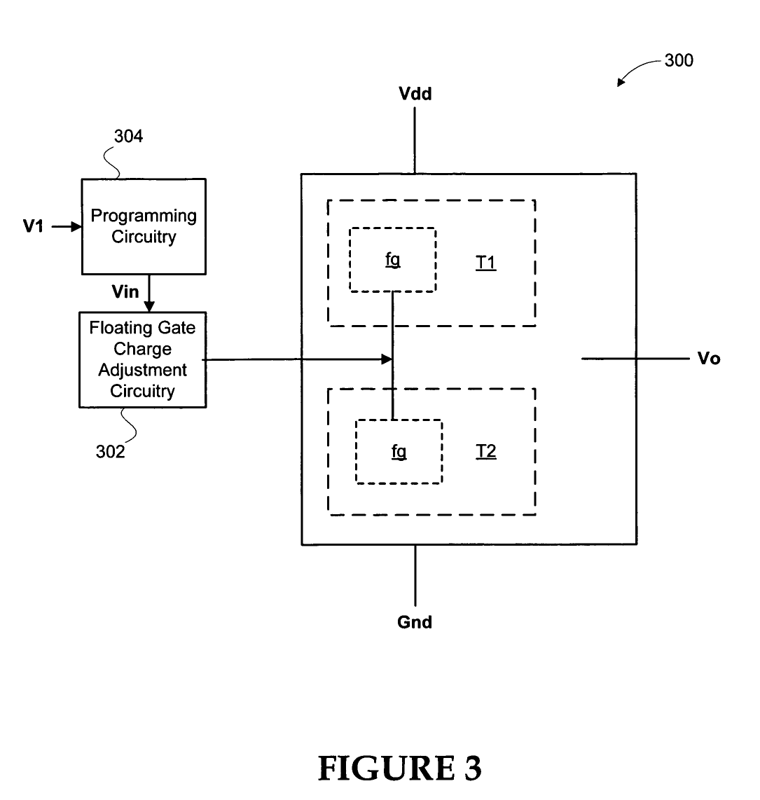

FIG. 3 is a block diagram of logic circuit 300 with a charge adjustment circuit and a programming circuit that is arranged to control and provide high voltage supply to the charge adjustment circuit.

Logic circuit 300 and floating gate charge adjustment circuit 302 are arranged to operate as described above for logic circuit 200 and floating gate charge adjustment circuit 202. Programming circuit 304 is arranged to receive a V1 and provide Vin to floating gate charge adjustment circuit 302, which in response provides a voltage coupled to the floating gate fg.

During an erase operation in one embodiment, electrons are removed from floating gate fg, thereby adjusting a switch point voltage of logic circuit 300 such that output voltage Vo corresponds to “0” when supply voltage is applied to the logic circuit. During a program operation, electrons are inserted into floating gate fg, thereby adjusting the switch point voltage of logic circuit 300 such that Vo corresponds to “1” when supply voltage is applied to the logic circuit. Thus, during program and erase operations, the switch point voltages of the NVM cell are changed. During a read operation, supply voltages Vdd and Gnd are applied to logic circuit 300. In response, output voltage Vo reflects a bit value based on the stored charges in the floating gate.

The FETs of the NVM cell may include at least one of a Metal-Oxide Field Effect Transistor (MOSFET), a FinFET, and a Metal-Semiconductor Field Effect Transistor (MESFET). Furthermore, the shared gate terminal is adapted to be charged by at least one of impact-ionized hot-electron injection, Fowler-Nordheim (FN) tunneling, channel hot-electron tunneling, and band-to-band tunneling induced electron injection. The shared gate terminal may be discharged by FN tunneling.

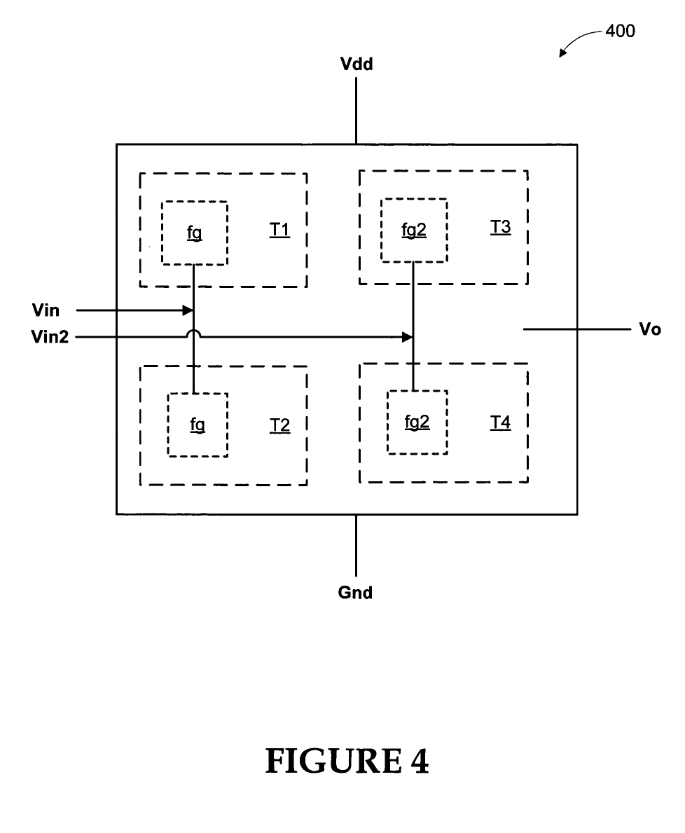

FIG. 4 is a block diagram of four-transistor, retention-enhanced, dual shared gate logic circuit 400.

Logic circuit 400 includes two transistor pairs T1, T2 and T3, T4 with each transistor pair sharing a floating gate. First input voltage Vin is coupled to first shared floating gate fg and second input voltage Vin2 is coupled to second shared floating gate fg2 for programming the floating gates as described previously.

In one embodiment, the transistor pairs may be arranged to operate as a NOR circuit. In another embodiment, the transistor pairs may be arranged to operate as a NAND circuit. In either embodiment, output voltage Vo corresponds to “0” or “1” depending on the charge levels of the floating gates as programmed by the input voltages. Other logic circuits such as XOR, XNOR, and the like, may be implemented without departing from a scope and spirit of the invention.

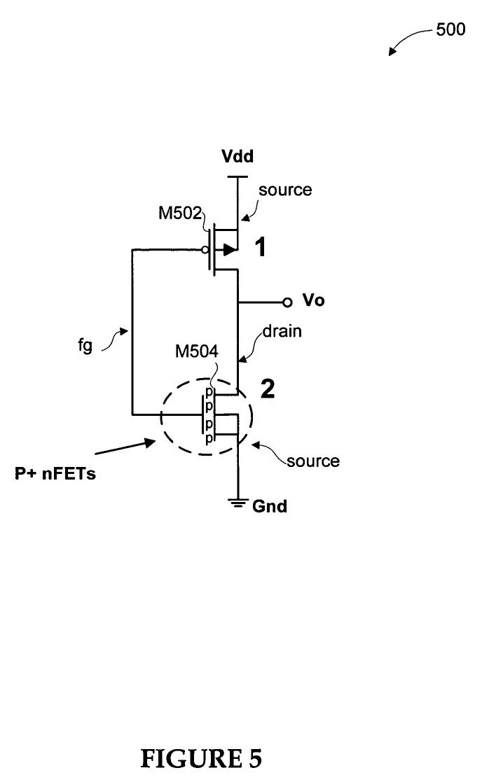

FIG. 5 schematically illustrates dual transistor, retention-enhanced, shared gate logic circuit 500. Logic circuit 500 is configured to operate as an inverter and includes two field effect transistors (FETs) that share a floating gate terminal. One of the FETs (M502) is p-type, the other (M504) n-type. The shared gate (fg) is doped with implants of p-type.

In one embodiment, a source terminal of M502 is coupled to high supply voltage Vdd and a drain terminal of second FET M504 is coupled to a drain terminal of first FET M502 such that output voltage Vo is provided from the drain terminal of second FET M502. A source terminal of second FET M504 is coupled to low supply voltage Gnd and shared gate terminal fg is coupled to an input voltage for programming the logic circuit.

NVM cell retention is generally dominated by n-FET long-term detention. If the n-FET has an n+ polysilicon gate, it has worse retention. p-FETs store charges longer than n-FETs for a given oxide thickness. Doping of the shared gate with p-type impurities enhances the retention capability of the NVM cell.

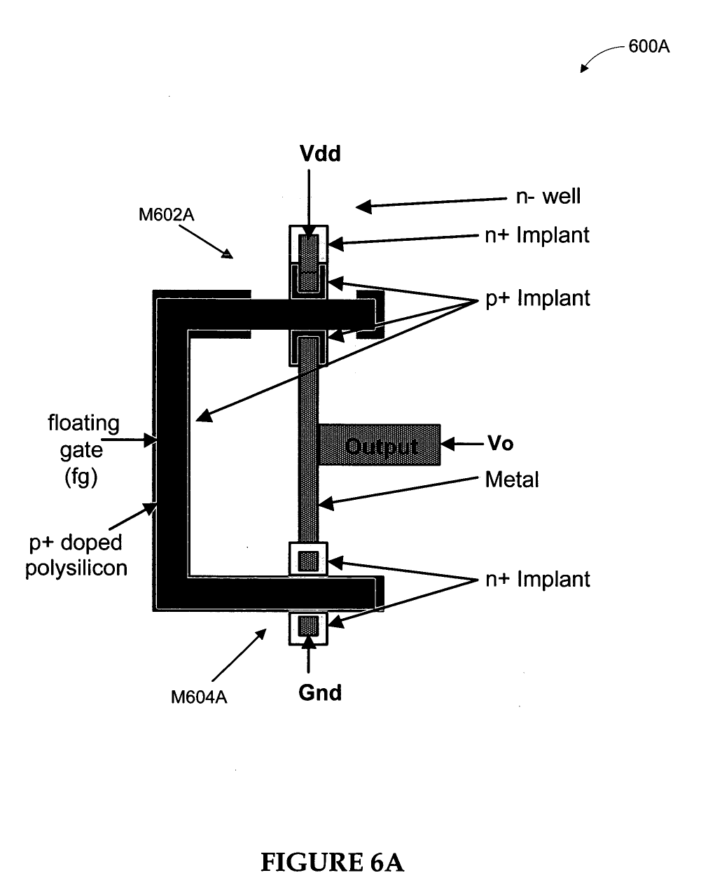

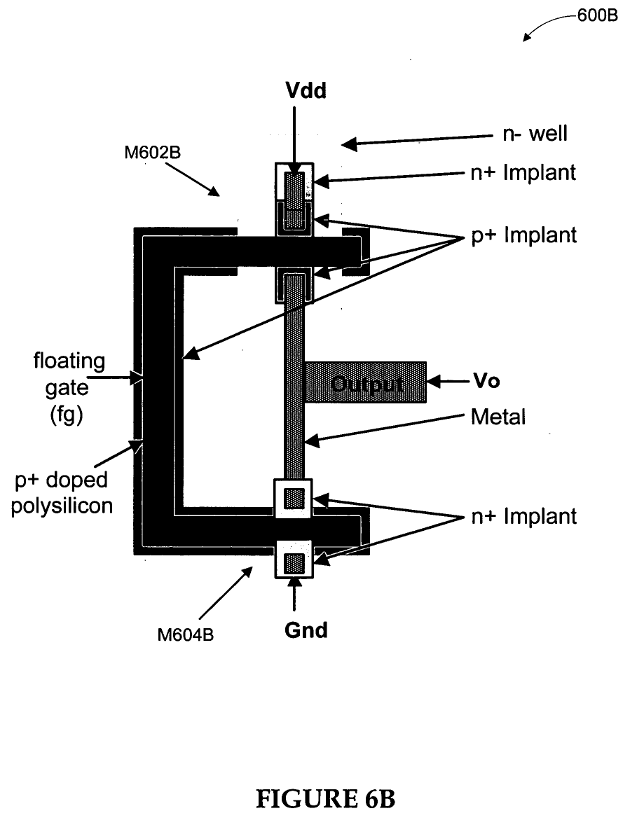

FIG. 6A is a conceptual top view of dual transistor logic circuit 600A comprising two MOSFETs with a shared gate entirely doped with p+ implants according to one embodiment.

Dual transistor logic circuit 600A includes first transistor M602A, which is formed over an n-well on a substrate (not shown). A first and a second surface region doped with p+implants within the n-well define a first channel, over which a portion of the shared floating gate (fg) is disposed. High supply voltage Vdd is provided to a contact region over an n− implant doped surface region that is separated from the p+ doped first surface region by a field oxide layer (not shown).

Second transistor M604A is formed over a p-well. In another embodiment, M604A may be formed directly over p- implant doped substrate. Similar to M602A, M604A has a portion of its shared floating gate disposed over a second channel. The second channel is defined by two surface regions doped with n− implants. A low supply voltage (e.g. ground) is provided to the n− implant doped surface region on the exterior side of the transistor structure.

The n− implant doped surface region on the interior side of the transistor structure and the second p+ implant doped surface region are separated by another field oxide layer. A contact region over these two surface regions is arranged to provide output voltage Vo.

As shown in the figure, M602A and M604A share floating gate fg. Floating gate fg is shown entirely doped with p+ implants in FIG. 6A. As explained previously, doping of the shared floating gate with p+ implants enables enhancement of the retention capability of dual transistor logic circuit 600A when it is used as an NVM cell.

FIG. 6B is a conceptual top view of dual transistor logic circuit 600B comprising two MOSFETs with a shared gate partially doped with p+ implants according to another embodiment.

Parts of logic circuit 600B that are similarly named in logic circuit 600A of FIG. 6A are arranged to function in a likewise manner. In logic circuit 600B, shared floating gate is, however, constructed differently. Instead of being entirely doped with p+ implants, shared floating gate fg is doped partially with p+ implants and partially with n− implants to achieve better alignment.

Through partial doping of the shared floating gate with p+ implants, retention of the NVM cell comprising dual transistor logic circuit 600B is enhanced. In addition, p+ doping of the polysilicon n-FET increases a threshold voltage of the transistor resulting in reduced power consumption.

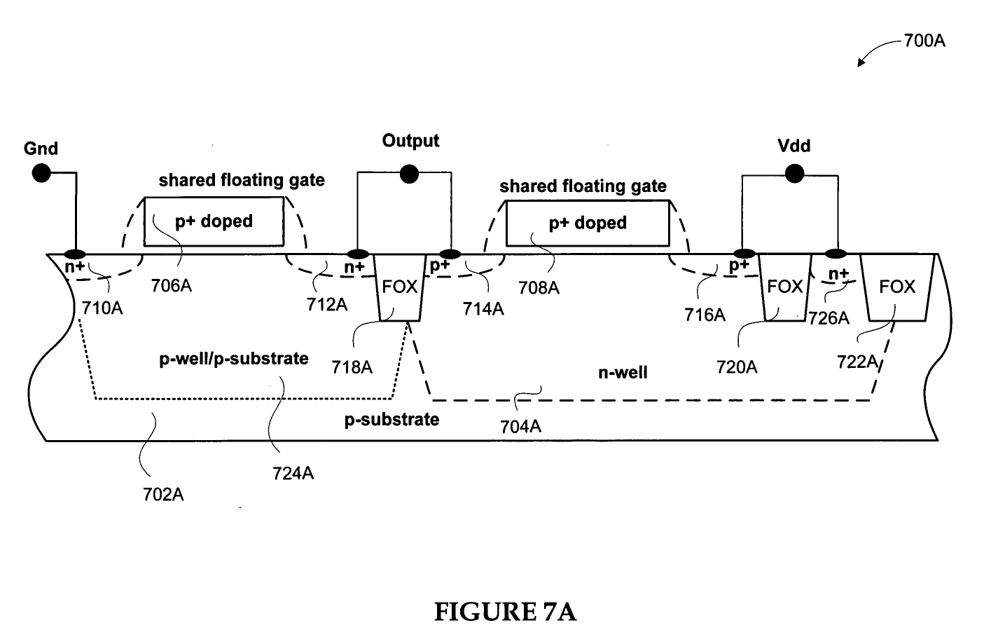

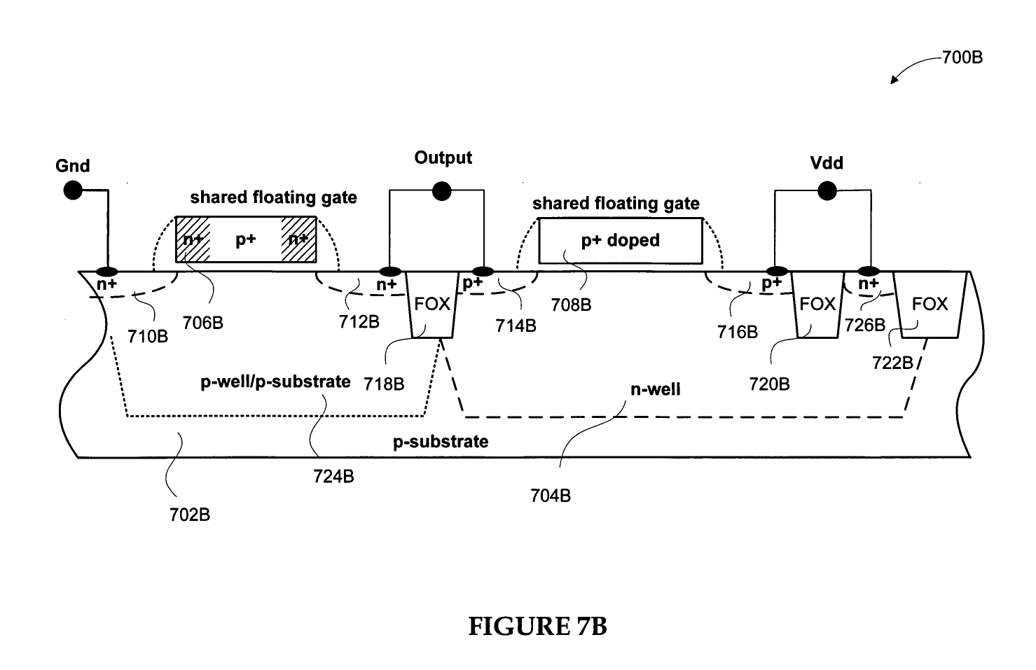

FIG. 7A is a cross-sectional view of dual transistor logic circuit 700A with the shared gate entirely doped with p+ implants according to one embodiment.

Dual transistor logic circuit 700A may be formed by substrate 702A that includes impurities of p-type. p-well 724A within substrate 702A includes impurities of p-type. Logic circuit 700A further includes in p-well 724A surface regions 710A and 712A that include impurities of n-type and define a first channel within the p-well. A portion of the shared gate (706A) is disposed over the first channel and has doped implants of p-type impurities. n-well 704A in substrate 702A includes impurities of n-type. Two additional surface regions 714A and 716A within the n-well include impurities of p-type and define a second channel within the n-well. A fifth surface region (726A) within the n-well includes impurities of n-type. A second portion of the shared gate (708A) is disposed over the second channel and has doped implants of p-type impurities.

Logic circuit 700A also includes a contact region over surface region 710A in p-well 724A arranged to receive low supply voltage Gnd and three field oxide layers. First field oxide layer 718A is between surface regions 712A and 714A, which define the second contact region, and is arranged to provide output voltage Vo. Second field oxide layer 722A is between surface region 716A and surface region 726A defining a third contact region that is arranged to receive high supply voltage Vdd. Third field oxide layer 720A is between n-well 704A and substrate 702A or other well structure along an opposite edge of n-well 704A with respect to first field oxide layer 718A.

The shared floating gate is arranged to receive the coupled voltage for programming logic circuit 700A. In another embodiment, a portion of the shared gate disposed over the first channel may be doped partially or completely with implants of p-type and n-type impurities.

Logic circuit 700A maybe Silicon-On-Insulator (SOI) type and the substrate may include a relatively thin layer of Si deposited over a thin film of oxide embedded onto a relatively thick layer of Si. Logic circuit 700A may also be Silicon-On-Sapphire (SOS) type and the substrate may include a relatively thin layer of Si over sapphire (Al₂O₃). In a further embodiment, Logic circuit 700A may be GaAs type and the substrate may include a thin layer of Ga deposited over a layer of As.

FIG. 7B is a cross-sectional view of dual transistor logic circuit 700B with the shared gate doped with p+ and n- implants according to another embodiment.

Parts of logic circuit 700B that are similarly numbered in logic circuit 700A of FIG. 7A are arranged to function in a likewise manner. Shared floating gate of logic circuit 700B is constructed differently.

As shown in the figure, first portion of shared gate 706B may be doped with p+ implants in the center and n+ implants on each side forming a band around the p+ doped center section. Furthermore, the entire shared floating gate (portions 706B and 708B), or one portion of the shared floating gate may be constructed as described.

Partial doping of the shared floating gate with p+ implants enhances retention of an NVM cell comprising logic circuit 700B. In addition, p+ doping of the polysilicon n-FET increases a threshold voltage of the transistor resulting in reduced power consumption.

In a further embodiment, p-well n-FET channel doping and anti punch-through ion implants may be omitted resulting in p-well 724B and substrate 704B being the same material. This may result in a reduction of the transistor's threshold voltage leading to increased power consumption due to minority carriers passing through the channel at lower threshold voltages. However, added simplicity of this embodiment may make it a preferable implementation for some dual transistor NVM cell designs.

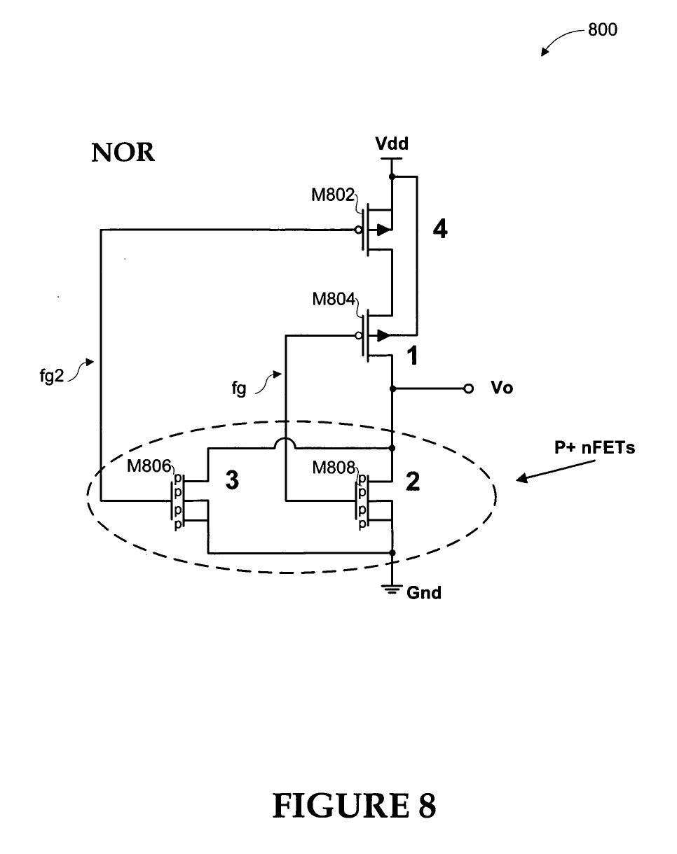

FIG. 8 schematically illustrates four transistor logic circuit 800 in a NOR configuration. Logic circuit 800 includes FETs M802, M804, M806, and M808. M802 and M806 share floating gate fg2. M804 and M808 share floating gate fg.

A drain terminal of the third FET (M806) is coupled to the drain terminal of the first FET (M804) and the drain terminal of the second FET (M808). A source terminal of M806 is coupled to the source terminal of M808 and low supply voltage Gnd. A drain terminal of the fourth FET (M802) is coupled to the source terminal of the first FET (M804). A source terminal of M802 is coupled to high supply voltage Vdd. Charge levels of the shared gates are adjusted by a first and second programming voltages as described previously in conjunction with FIG. 4.

Shared gates may be doped with p-type impurities partially or completely enhancing the retention capability of logic circuit 800 as an NVM cell.

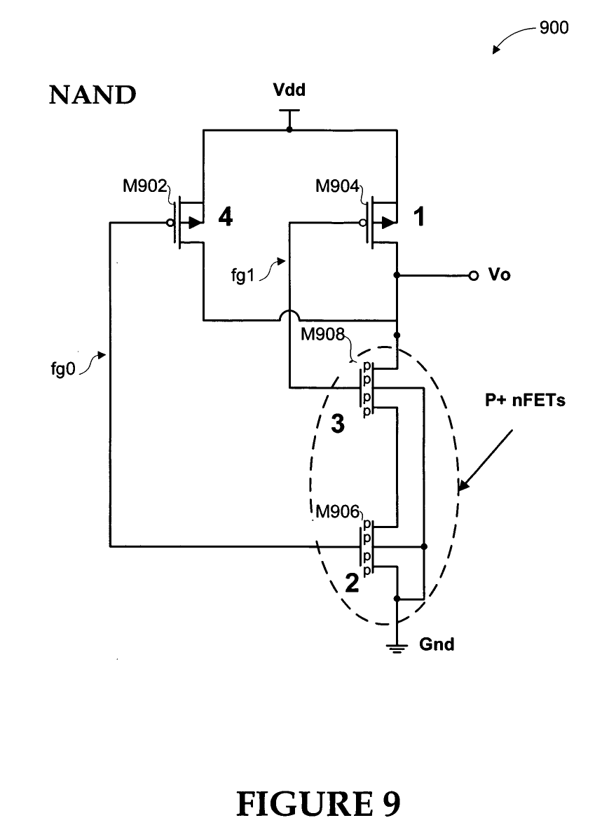

FIG. 9 schematically illustrates four transistor logic circuit 900 in a NAND configuration. Logic circuit 900 includes FETs M902, M904, M906, and M908. M902 and M908 share floating gate fg0. M904 and M906 share floating gate fg1.

In the NAND configuration logic circuit 900, the drain terminal of the third FET (M906) is coupled to the drain terminal of the first FET (M904) and a drain terminal of the fourth FET (M902). The source terminal of M906 is coupled to the drain terminal of the second FET (M908). A source terminal of M902 is coupled to the source terminal of the M904 and high supply voltage Vdd.

As in logic circuit 800 of FIG. 8, the shared gates fg0 and fg1 may be doped with p-type impurities partially or completely enhancing the retention capability of logic circuit 900 as an NVM cell.

This description is just one implementation. Other implementations may be made, without departing from the scope and spirit of the invention. In one embodiment, second and third FETs M906 and M908 may be p+ doped polysilicon n-type FETs.

The examples provided above in FIGS. 8 and 9 are for illustration purposes and do not constitute a limitation on the present invention. Other embodiments may be implemented using other logic circuit types and transistor types without departing from the scope and spirit of the invention. Further embodiments may include FinFETs, dual gate MOSFETs, MESFETs, GaAs FETs, and other MOS devices.

The above specification, examples and data provide a complete description of the manufacture and use of the composition of the invention. Since many embodiments of the invention can be made without departing from the spirit and scope of the invention, the invention resides in the claims hereinafter appended.

What is claimed is:

1. A logic circuit, comprising:
a first field effect transistor (FET) circuit of first type; and
a second FET circuit of second type that is coupled to the first FET circuit, wherein the first FET circuit and the second FET circuit share a floating gate terminal that includes at least in part doped implants of first type.

2. The circuit of claim 1, wherein
the entire shared floating gate terminal is doped with implants of first type.

3. The circuit of claim 1, wherein
a source terminal of the first FET circuit is coupled to a high supply voltage;
a drain terminal of the second FET circuit is coupled to a drain terminal of the first FET circuit such that an output voltage is provided from the drain terminal of the second FET circuit;
a source terminal of the second FET circuit is coupled to a low supply voltage; and
the shared gate terminal is coupled to an input voltage for programming the logic circuit such that the logic circuit is arranged to operate as a non-volatile memory cell.

4. The circuit of claim 3, further comprising:
a charge adjustment circuit is arranged to be coupled with the input voltage for programming and adjusting a charge storage level of the shared floating gate of the logic circuit based on an adjustment signal such that the logic circuit is employed as an enhanced retention non-volatile memory (NVM) cell.

5. The circuit of claim 3, further comprising:
a programming circuit is arranged to provide the input voltage for the charge adjustment circuit based on a programming signal.

6. The circuit of claim 3, further comprising:
a third FET circuit of second type and a fourth FET circuit of first type such that the logic circuit is configured to operate as a NOR circuit, wherein
a drain terminal of the third FET circuit is coupled to the drain terminal of the first FET circuit and the drain terminal of the second FET circuit;
a source terminal of the third FET circuit is coupled to the source terminal of the second FET circuit and a low supply voltage;
a drain terminal of the fourth FET circuit is coupled to the source terminal of the first FET circuit;
a source terminal of the fourth FET circuit is coupled to a high supply voltage; and
the third FET circuit and the fourth FET circuit share a second floating gate terminal that is arranged to receive a second input voltage.

7. The circuit of claim 3, further comprising:
a third FET circuit of second type and a fourth FET circuit of first type such that the logic circuit is configured to operate as a NAND circuit, wherein
a drain terminal of the third FET circuit is coupled to the drain terminal of the first FET circuit and a drain terminal of the fourth FET circuit;
a source terminal of the third FET circuit is coupled to the drain terminal of the second FET circuit;
a source terminal of the fourth FET circuit is coupled to the source terminal of the first FET circuit and a high supply voltage; and
the third FET circuit and the fourth FET circuit share a second floating gate terminal that is arranged to receive a second input voltage.

8. The circuit of claim 1, wherein
the first type is p-type and the second type is n-type.

9. The circuit of claim 1, wherein
the first FET circuit comprises at least one of: a MOSFET, a FinFET, and a MESFET.

10. The circuit of claim 1, wherein
the shared gate terminal is adapted to be charged by at least one of: impact-ionized hot-electron injection, Fowler-Nordheim (FN) tunneling, channel hot-electron injection, and band-to-band tunneling induced electron injection.

11. The circuit of claim 1, wherein
the shared gate terminal is adapted to be discharged by FN tunneling, impact-ionization induced hot-hole injection, and band-to-band tunneling induced hot-hole injection.

12. The circuit of claim 1, wherein
the entire shared floating gate terminal is doped with implants of p-type.

13. The circuit of claim 1, wherein
the shared floating gate terminal is partially doped with implants of p-type and n-type;

14. A dual transistor, NVM cell circuit, comprising:
a substrate that includes impurities of p-type;
a p-well within the substrate that includes impurities of p-type;
a first surface region and a second surface region in the p-well that include impurities of n-type and define a first channel within the p-well;
a first portion of a shared gate disposed over the first channel, the first portion of the shared gate having doped implants of p-type impurities;
an n-well in the substrate that includes impurities of n-type;
a third surface region and a fourth surface region within the n-well that include impurities of p-type and define a second channel within the n-well;
a fifth surface region within the n-well that includes impurities of n-type; and
a second portion of the shared gate disposed over the second channel, the second portion of the shared gate having doped implants of p-type impurities.

15. The circuit of claim 14, further comprising:
a first contact region over the first surface region that is arranged to receive a low supply voltage;
a first field oxide layer between the second surface region and the third surface region that defines a second contact region, wherein the second contact region is arranged to provide an output voltage;
a second field oxide layer between the fourth surface region and the fifth surface region that defines a third contact region, wherein the third contact region is arranged to receive a high supply voltage; and
a third field oxide layer between the n-well and the substrate along an opposite edge of the n-well with respect to the first field oxide layer.

16. The circuit of claim 14, wherein
the shared gate is arranged to receive an input voltage for programming the NVM cell circuit.

17. The circuit of claim 14, wherein
the first portion of the shared gate disposed over the first channel is doped partially with implants of p-type and n-type impurities.

18. The circuit of claim 14, wherein
the p-well includes substantially same concentration of impurities of p-type as the substrate.

19. The circuit of claim 14, wherein
the circuit is of Silicon-On-Insulator (SOI) type and the substrate comprises a relatively thin layer of Si deposited over a thin film of oxide embedded onto a relatively thick layer of Si.

20. The circuit of claim 14, wherein
the circuit is of Silicon-On-Sapphire (SOS) type and the substrate comprises a relatively thin layer of Si over sapphire (Al₂O₃).

21. The circuit of claim 14, wherein
the circuit is of GaAs type and the substrate comprises a thin layer of Ga deposited over a layer of As.

22. A method for creating a dual transistor, NVM cell circuit comprising:
forming a substrate that includes doped implants of a first type;
forming a first well within the substrate that includes doped implants of a first type;
forming a first surface region and a second surface region in the first well that include impurities of a second type and define a first channel within the substrate;
forming a second well in the substrate that includes impurities of the second type;
forming a third surface region and a fourth surface region within the second well that include impurities of the first type and define a second channel within the second well;
forming a fifth surface region within the second well that includes impurities of the first type; and
forming a shared gate disposed over the first channel and the second channel, the shared gate having doped implants of the first type impurities.

23. The method of claim 22, further comprising:
forming a first contact region over the first surface region that is arranged to receive a low supply voltage;
forming a first field oxide layer between the second surface region and the third surface region that defines a second contact region, wherein the second contact region is arranged to provide an output voltage;
forming a second field oxide layer between the fourth surface region and the fifth surface region that defines a third contact region, wherein the third contact region is arranged to receive a high supply voltage; and
forming a third field oxide layer between the well and the substrate along an opposite edge of the well with respect to the first field oxide layer.

24. The method of claim 23, wherein a portion of the shared gate disposed over the first channel is partially doped with implants of the first type and the second type.

25. The method of claim 23, wherein the doped implants of the first type includes p-type and the doped implants of the second type includes n-type.

26. A method for creating a dual transistor, NVM cell circuit comprising:
forming a substrate that includes doped implants of a first type;
forming a first surface region and a second surface region in the substrate that include impurities of a second type and define a first channel within the substrate;
forming a well in the substrate that includes impurities of the second type;
forming a third surface region and a fourth surface region within the well that include impurities of the first type and define a second channel within the well;
forming a fifth surface region within the well; and
forming a shared gate disposed over the first channel and the second channel, the shared gate having doped implants of the first type impurities.

27. The method of claim 26, further comprising:
forming a first contact region over the first surface region that is arranged to receive a low supply voltage;
forming a first field oxide layer between the second surface region and the third surface region that defines a second contact region, wherein the second contact region is arranged to provide an output voltage;
forming a second field oxide layer between the fourth surface region and the fifth surface region that defines a third contact region, wherein the third contact region is arranged to receive a high supply voltage; and
forming a third field oxide layer between the well and the substrate along an opposite edge of the well with respect to the first field oxide layer.

28. The method of claim 27, wherein a portion of the shared gate disposed over the first channel is partially doped with implants of the first type and the second type.

29. The method of claim 27, wherein the doped implants of the first type includes p-type and the doped implants of the second type includes n-type.
